(19) United States
(12) Patent Application Publication
(10) Pub. No.: US 2025/0244452 A1
(43) Pub. Date: Jul. 31, 2025

(54) Method of Automatically Determining Sensor Placement in a Target Environment

(71) Applicant: Hong Kong Applied Science And Technology Research Institute Co., Ltd., Shatin, N.T. (HK)

(72) Inventors: Yuen-Hei Yeung, Kowloon (HK); Xinghua Zhu, Shenzhen (CN); Zhuojun Chen, Guangzhou (CN); Hang Chen, Kowloon Bay (HK); Dongzhe Su, Shenzhen (CN); Shijun Fan, Fanling, NT (HK)

(21) Appl. No.: 18/427,001

(22) Filed: Jan. 30, 2024

(51) Int. Cl. G01S 7/497; G01S 17/00; G01S 17/89; G01S 17/931; G06F 30/27

(52) U.S. Cl. CPC G01S 7/497; G01S 17/006; G01S 17/89; G01S 17/931; G06F 30/27

(57) ABSTRACT

A method of automatically determining sensor placement in a target environment. The method comprises receiving as inputs: a three-dimensional (3D) map of the target environment; a number of a plurality of sensors to be placed in the target environment; a set of placement configuration parameters for the plurality of sensors; and a set of constraints for the plurality of sensors in the target environment. The method includes, based on the received inputs, using a simulation platform to simulate, based on one or more defined conditions in the target environment, operation of the plurality of sensors to generate a dataset comprising simulated output data for the plurality of sensors; and using a Reinforcement Learning (RL) algorithm to determine from the dataset comprising simulated output data for the plurality of sensors an optimized or at least an improved set of placement configuration parameters for the plurality of sensors.

### FIELD OF THE INVENTION

The present invention relates to a method of automatically determining sensor placement in a target environment and particularly, but not exclusively, to a method of automatically determining light detection and ranging (LiDAR) sensor placement in a target environment comprising a road traffic environment.

### BACKGROUND OF THE INVENTION

Autonomous Vehicles (AVs) are vehicles configured with an aim to assist or replace human drivers by automating at least some of the driving tasks. AVs utilize the Vehicle-to-Everything (V2X) communications protocol, which is a vehicular communication protocol configured to deliver information from a vehicle to any entity that may affect the vehicle, and vice versa. The V2X protocol assists by enabling communicating information and/or data exchanges between vehicle on-board units (OBUs) and, for example, roadside infrastructure for road safety, management, and/or threat determination purposes. A V2X system incorporates other more specific types of communications including, but not limited to, Vehicle-to-Infrastructure (V2I), Vehicle-to-Vehicle (V2V), Vehicle-to-Pedestrian (V2P), Vehicle-to-Device (V2D), and Vehicle-to-Grid (V2G), etc.

The roadside infrastructure typically includes sensors for generating point cloud data; a point cloud comprising a collection of individual data points in a three-dimensional space, with each data point being assigned with a set of coordinates within the X, Y, and Z axes. Point cloud data is particularly useful in object detection, path planning and vehicle control, etc. The roadside sensors are capable of generating point cloud data, and subsequently, transmitting the point cloud data to edge servers or the like through Cellular-Vehicle-to-Everything (C-V2X) channels.

The roadside infrastructure sensors typically include LiDAR sensors providing extended fields of view (FOV) for connected AVs to improve safety and efficiency of traffic on the road.

The installation and adjustment of LiDAR sensors in a roadside environment requires construction work from certified engineers and often requires road permit applications for such construction work. It also raises facility management issues. The construction and installation of the roadside sensors can be costly in terms of both budget considerations and labor effort. Conventionally, installation of roadside sensors depends on empirical estimations for the position, height, and angle placement configuration parameters of the sensors. Such parameters affect the quality of roadside perception. Appropriate or better values of the placement configuration parameters for the LiDAR sensors provide a more comprehensive coverage and result in improved quality of the LiDAR point cloud scans.

Some known methods of determining roadside sensor placement focus on constructing mathematical formulations to provide numerical values of sensor placement configuration parameters. However, such methods typically require extensive trial and error using the mathematical formulations to attempt to obtain improved numerical values for the sensor placement configuration parameters. The trial-and-error approach is akin to other methods which seek to determine improved sensor placement configuration parameters on a case-by-case basis which fails to take account of what may be learned about common scenarios and applied to such methods.

Some known methods for machine learning based on traffic datasets focus on the perspective of vehicles in the target environment, but do not consider the roadside perspective.

A pragmatic, cost-efficient, and systematic approach for roadside LiDAR sensor placement improvement or optimization would help to reduce construction costs of V2X systems, improve roadside perception accuracy, and improve roadside-assisted perception and decision accuracy for connected AVs, among other things.

There is a need to develop a method to improve or optimize placement of sensors such as LiDAR sensors in a target environment such as a roadside infrastructure environment.

### OBJECTS OF THE INVENTION

An object of the invention is to mitigate or obviate to some degree one or more problems associated with known placement of sensors such as LiDAR sensors in a target environment such as, for example, a roadside infrastructure environment or roadside traffic environment.

Another object of the invention is to provide an improved method for simulating placement of sensors such as LiDAR sensors in a roadside infrastructure environment.

Another object of the invention is to provide an improved method for modelling placement of sensors such as LiDAR sensors in a roadside infrastructure environment.

The above objects are met by the combination of features of the main claims; the sub-claims disclose further advantageous embodiments of the invention.

One skilled in the art will derive from the following description other objects of the invention. Therefore, the foregoing statements of object are not exhaustive and serve merely to illustrate some of the many objects of the present invention.

### SUMMARY OF THE INVENTION

The method provides both a method for modelling/simulating placement of sensors in a target environment for one or more common scenarios and an applied method for modelling/simulating placement of sensors in a real-world target environment. Placement data learned from the method for modelling/simulating placement of sensors in a target environment for one or more common scenarios can be imported into the applied method for modelling/simulating placement of sensors in a real-world target environment to speed up computation effort.

In a first main aspect, the invention provides a method of automatically determining roadside sensor placement in a target environment. The method comprises receiving as inputs: a three-dimensional (3D) map of the target environment; a number of a plurality of sensors to be placed in the target environment; a set of placement configuration parameters for the plurality of sensors; and a set of constraints for the plurality of sensors in the target environment. The method includes, based on the received inputs, using a simulation platform such as a game engine-based simulator to simulate, based on one or more defined conditions in the target environment, operation of the plurality of sensors to generate a dataset comprising simulated output data for the plurality of sensors. In a next step, the method comprises using a Reinforcement Learning (RL) algorithm or model to determine from the dataset comprising simulated output data for the plurality of sensors an optimized or at least an improved set of placement configuration parameters for the plurality of sensors.

The simulation platform such as the game engine-based simulator uses computer graphics for realistic scene rendering.

The RL algorithm or model comprises a machine learning approach where an agent learns to make sequential decisions in a target environment to maximize a reward. The RL model may comprise a neural network as its underlying architecture.

Preferably, the method comprises using the simulation platform to generate respective datasets for a plurality of target environment scenarios and using the respective datasets to train the RL algorithm to determine optimized or at least improved sets of placement configuration parameters for the plurality of sensors for the plurality of target environment scenarios.

One of the received inputs may comprise an optimized or at least an improved set of placement configuration parameters for one of the plurality of target environment scenarios.

Preferably, the method is applied iteratively for a plurality of sensor model types, the sensor model types having different values for the constraints in the target environment, to thereby determine an optimized or at least an improved set of placement configuration parameters for the plurality of sensors including a preferred or optimal sensor model type.

Preferably, a reward parameter for the RL algorithm comprises simulated coverage area for each of the plurality of sensors, but, in other embodiments, the reward parameter can be based on other characteristics of the target environment. The simulated coverage area for each of the plurality of sensors may comprise simulated 3D point cloud data for each of the plurality of sensors.

The simulated 3D point cloud data for each of the plurality of sensors may be approximated. The point cloud data for each of the plurality of sensors may be approximated based on point distance, point cloud density, and point distribution uniformity. The 3D point cloud data for each of the plurality of sensors may be approximated by representing the 3D point cloud data as a 2D grid and applying the L1 norm (Manhattan Distance) to each data point in 2D grid. This may comprise dividing the 2D grid into rectangular boxes, assigning “x” and “y” coordinates to each data point in the rectangular boxes, and applying the L1 norm (Manhattan Distance) to each data point in the rectangular boxes.

In one embodiment, the method comprises, in one or more iterations, reducing the number of a plurality of sensors to be placed in the target environment and determine an optimized or at least an improved set of placement configuration parameters for the reduced number of sensors.

In one embodiment, the method comprises inputting the set of placement configuration parameters for the plurality of sensors as an initial set of placement configuration parameters and iteratively implementing the method for respective adjustments of one or more of the placement configuration parameters to determine an optimized or at least an improved set of placement configuration parameters for the plurality of sensors.

In one embodiment, one or more weighting values are applied to one or more of the constraints in the set of constraints for the plurality of sensors in the target environment.

Preferably, the plurality of sensors comprises LiDAR sensors and the target environment comprises a road traffic environment.

Preferably, the simulation platform comprises a Car Learning to ACT (CARLA™) simulator for autonomous driving research, but, in other embodiments, the simulation platform may comprise any one of an Autoware™ (Gazebo) simulator, an Airsim™ (UE4 & Unity) simulator, a TORCS™ (Open GL) simulator, or any suitable simulator.

Preferably, the RL algorithm comprises a universal RL model such as, for example, AlphaGo™.

In a second main aspect, the invention provides an apparatus for automatically determining roadside sensor placement in a target environment. The apparatus comprises a memory for storing machine-readable instructions and a processor for executing said machine-readable instructions to thereby configure the processor to implement the steps of the method according to the first aspect of the invention.

The apparatus may be a standalone computer processing apparatus.

In one embodiment, the apparatus is implemented in a roadside unit (RSU), or an edge server, or a node device of a network, the network comprising, for example, a Vehicular Ad Hoc Network (VANET).

In a third main aspect, the invention provides a non-transitory computer readable medium comprising machine-readable instructions which, when executed by a processor, causes the processor to implement the steps of the method according to the first aspect of the invention.

The summary of the invention does not necessarily disclose all the features essential for defining the invention; the invention may reside in a sub-combination of the disclosed features.

### BRIEF DESCRIPTION OF THE DRAWINGS

The foregoing and further features of the present invention will be apparent from the following description of preferred embodiments which are provided by way of example only in connection with the accompanying figures, of which:

FIG. 1 is a schematic diagram illustrating one embodiment of a road management system;

FIG. 2 is a schematic flow diagram of one embodiment of an applied method in accordance with the invention;

FIG. 3 is a schematic flow diagram of another embodiment of an applied method in accordance with the invention;

FIG. 4 is a schematic flow diagram of one embodiment of a training method in accordance with the invention;

FIG. 5A is a plan view of a bird's eye view (BEV) of a segmentation map of a roadside scenario;

FIG. 5B is a plan view of the BEV of the segmentation map of FIG. 5A showing sensor placement at different timestamps;

FIG. 6A is a plan view of binary mask of a roadside scenario;

FIG. 6B is a plan view of the binary mask of FIG. 5A showing sensor placement at different timestamps;

FIG. 7A is a binary mask of a roadside scenario for a first example case of a model learning environment;

FIG. 7B is a binary mask of the roadside scenario of FIG. 6A for another example case of a model learning environment;

FIG. 8A is a plan view of a targeted region of a roadside scenario;

FIG. 8B is LiDAR sensor 3D point cloud scan data projected onto a 2D representation with selected circular regions for determining a surrogate metric;

FIG. 8C is LiDAR sensor 3D point cloud scan data projected onto a 2D representation with grid regions for determining a surrogate metric;

FIG. 9A is a plan view of point cloud scan data for a roadside scenario for assigning traffic index values;

FIG. 9B is a plan view the point cloud scan data of FIG. 9A showing areas with higher assigned traffic index values;

FIG. 10A is a plan view of a roadside scenario showing the center point between sensors;

FIG. 10B is a side view of the roadside scenario of FIG. 10A showing a distance measurement between sensors; and

FIG. 10C shows sensor pitch angle relationship.

### DESCRIPTION OF PREFERRED EMBODIMENTS

The following description is of preferred embodiments by way of example only and without limitation to the combination of features necessary for carrying the invention into effect.

Reference in this specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments, but not other embodiments.

It should be understood that the elements shown in the figures may be implemented in various forms of hardware, software, or combinations thereof. These elements may be implemented in a combination of hardware and software on one or more appropriately programmed general-purpose devices, which may include a processor, memory, and input/output interfaces.

The present description illustrates the principles of the present invention. It will thus be appreciated that those skilled in the art will be able to devise various arrangements that, although not explicitly described or shown herein, embody the principles of the invention and are included within its spirit and scope.

Moreover, all statements herein reciting principles, aspects, and embodiments of the invention, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

Thus, for example, it will be appreciated by those skilled in the art that the diagrams presented herein represent conceptual views of systems or devices embodying the principles of the invention.

The functions of the various elements shown in the figures may be provided through the use of dedicated hardware as well as hardware capable of executing software in association with appropriate software. When provided by a processor, the functions may be provided by a single dedicated processor, by a single shared processor, or by a plurality of individual processors, some of which may be shared. Moreover, explicit use of the term “processor” or “controller” should not be construed to refer exclusively to hardware capable of executing software, and may implicitly include, without limitation, digital signal processor (“DSP”) hardware, read-only memory (“ROM”) for storing software, random access memory (“RAM”), and non-volatile storage.

In the claims hereof, any element expressed as a means for performing a specified function is intended to encompass any way of performing that function including, for example, a) a combination of circuit elements that performs that function or b) software in any form, including, therefore, firmware, microcode, or the like, combined with appropriate circuitry for executing that software to perform the function. The invention as defined by such claims resides in the fact that the functionalities provided by the various recited means are combined and brought together in the manner which the claims call for. It is thus regarded that any means that can provide those functionalities are equivalent to those shown herein.

In the following description, the terms “roadside infrastructure environment” and “roadside traffic environment” may be used interchangeably.

The present invention proposes an automatic roadside LiDAR sensor placement improvement or optimization method based on Reinforcement Learning (RL) and simulated data in the target environment. Decent quality of point cloud data is of vital importance to train robust deep learning models, e.g. object detection models for identifying vehicles and road users, and segmentation models for region partitioning and scene understanding. The present invention provides a unique method by combining RL and simulation-assisted LiDAR sensor scans to achieve high adaptability, accuracy, and efficiency in real-world scenarios to optimize roadside sensor placement. The present invention obviates or mitigates issues encountered with existing methods by using context-based optimization, eliminating the need for exhaustive search, and, in preferred embodiments, by dynamically adapting to different scenarios for optimal LiDAR placement configuration parameter generation.

In one embodiment, the invention comprises receiving a user-defined number of a plurality of sensors to be placed in a target environment based on a user-inputted 3D map of the target environment. Other user inputs include constraints relating to the placement of the sensors in the target environment. One such constraint is budget data, i.e., a maximum cost for the placement process preferably taking into account factors such as the cost of the sensors, labor and material costs, and other related construction/installation costs. An initial set of placement configuration parameters, e.g., location variables, may be inputted. In the case of the placement of LiDAR sensors, the placement configuration parameters may comprise location data such as location coordinates (x, y, z coordinates), height, and pitch and/or yaw angles of the sensors. A further input may be a defined condition or a set of defined conditions for the target environment such as a traffic flow level(s), for example. A further defined condition may be defined areas of the target environment where sensors cannot or should not be placed.

In this method, a simulation platform is used to simulate, based on the inputs, operation of the plurality of sensors to generate a dataset comprising simulated output data for the plurality of sensors. The generated dataset is then input to an RL algorithm or model to determine an optimized or at least an improved set of placement configuration parameters for the plurality of sensors.

In the case of LiDAR sensors, the generated dataset resulting from the simulation preferably comprises simulated point cloud data of the FOVs of each of the plurality of LiDAR sensors. In order to evaluate a reward metric for the RL algorithm, the simulated point cloud data for each of the plurality of LiDAR sensors is preferably projected into a 2D coordinate system such as, for example, a 2D grid to derive a value of the reward metric for the RL algorithm. The value of the reward metric for the RL algorithm comprises a value of optimization quality with a higher value indicating a higher optimization quality. The value of the reward metric for the RL algorithm is preferably based on a measure or calculated level of coverage by the plurality of LiDAR sensors of the target environment or defined areas of the target environment.

The afore-described embodiment of the invention can be considered as comprising an applied method for a real-world target environment.

In another embodiment, which can be considered as a training method for defined target environment scenarios, the invention provides a method of determining placement of sensors in a target environment for one or more defined scenarios. In the case of a defined scenario for a target environment comprising a road traffic environment, examples of such defined scenarios comprise a “T”-junction, a cross-roads, a road intersection, or a highway. The method of this embodiment includes receiving inputs such as a 3D map of the defined scenario under consideration, a number of a plurality of sensors to be placed in a target environment, sensor placement configuration parameters, and one or more constraints relating to the placement of the sensors in the target environment. A further input may be a defined condition or a set of conditions for the target environment such as a traffic flow level.

In this method, the simulation platform is used to simulate, based on the inputs, operation of the plurality of sensors to generate a dataset comprising simulated output data for the plurality of sensors in the defined scenario under consideration. The generated dataset is then input to an RL algorithm or model to determine an optimized or at least an improved set of placement configuration parameters for the plurality of sensors in the defined scenario under consideration.

The training method of this embodiment enables optimized or improved placement configuration parameters to be determined for the plurality of sensors for each of the defined scenarios. The optimized or improved placement configuration parameters for one or more of the defined scenarios may be imported into the applied method for a real-world target environment to reduce computation effort in the applied method when determining optimized or improved placement configuration parameters for the plurality of sensors in a user-defined target environment based on a user-inputted 3D map.

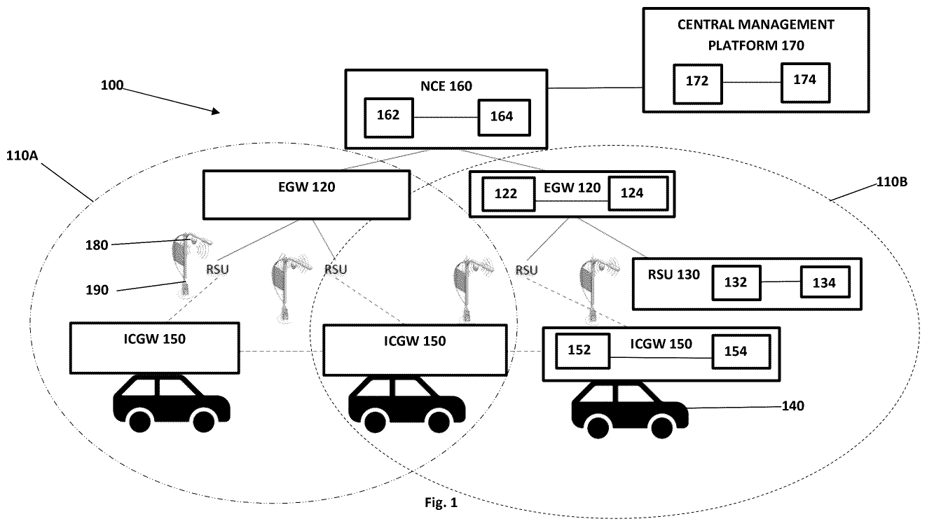

Referring to the drawings, FIG. 1 provides an example of a target environment in which the aspects of the method of the invention may be implemented, but it will be understood that this is provided merely by way of example and does not limit the target environments in which the method of the invention may be implemented.

Referring to FIG. 1, provided is a schematic diagram of a V2X based road management system 100. The system 100 is preferably a communications network-based system 100 arranged as a plurality of defined local geographical areas 110A, B, each defined local geographical area 110A, B being managed by and/or in data communication with a respective edge gateway module (EGW) 120. Each EGW 120 communicates with a respective network cooperation engine (NCE) 160 and each NCE 160 communicates with a central management platform 170.

Each EGW 120 preferably manages and is in communication with a plurality of roadside units (RSUs) 130. Each RSU 130 is preferably arranged alongside, adjacent, or near to any one or more of a road environment such as an intersection, a junction, a pedestrian crossing, a set of traffic lights, etc. such that each RSU has a line of sight to any vehicles located in or passing its near vicinity. Each EGW 120 comprises at least a memory 122 for storing machine-readable instructions and a processor 124 for executing said instructions to cause the EGW 120 to implement appropriate method steps. In a similar manner, each RSU 130 comprises at least a memory 132 for storing machine-readable instructions and a processor 134 for executing said instructions to cause the RSU 130 to implement appropriate method steps.

Vehicles 140 which are configured to operate within the network system 100 are each provisioned with a vehicle on-board data processing unit—hereinafter referred to as an in-car gateway module (ICGW) 150. The ICGW 150 may be a stand-alone unit configured to be installable into a vehicle 140 or it may comprise an existing data processing unit of the vehicle 140 having a memory 152 storing machine-readable instructions and a processor 154 for executing said instructions to cause the ICGW 150 to implement appropriate method steps. The ICGW 150 may comprise a V2X on-board unit (V2X-OBU).

Among other things, each ICGW 150 is preferably configured to provide V2X communication system access and information exchange with other ICGWs 150 and road infrastructure in the defined local geographical area 110A, B, to collect data from the vehicle on-board modules such as, for example, the speedometer and satellite positioning system, directly or indirectly exchange vehicle collected data with other local ICGWs 150, RSUs 130 and its respective EGW 120, use the vehicle collected data and data received from other local ICGWs 150, RSUs 130 and EGW 120 to determine threats and generate alarms, etc., and receive and issue V2X alarms (alerts) and notifications as well as receive traffic status information and recommendations.

Each EGW 120 is preferably configured to at least coordinate multiple RSUs 130 within its respective defined local geographical area 110A, B, monitor traffic in real-time including monitoring traffic congestion and traffic incidents such as accidents, intelligently implement local traffic management, collect data from local infrastructure such as, for example, traffic lights, sensors, cameras, local ICGWs 150 and RSUs 130 and its respective NCE 160, collect policies from its respective NCE 160, and to use collected data to determine threats and generate alarms, etc. Some of the sensors comprise LiDAR sensors 180, preferably mounted in association with a respective RSU 130 on suitable roadside infrastructure such as a lamppost 190 or the like. Each EGW 120 may be configured to determine from received and processed data specific data to be transmitted to a specific ICGW 150 in dependence on data received at said EGW 120 indicative of one or more parameters related to or associated with a vehicle of said specific ICGW 150. For example, a parameter such a street location may be utilized by the EGW 120 to determine which vehicles within its local geographical area 110A, B need to receive a specific alert, alarm, action, or indication of threat.

A plurality of EGWs 120 is preferably managed by and/or in data communication with a respective NCE 160 and, in turn, a plurality of NCEs 160 is preferably managed by and/or in data communication with a central management platform module 170. The system 100 may comprise only a single central management platform module 170 to cover a large geographical region such as, for example, a city, a county, or a state. Each NCE 160 comprises at least a memory 162 for storing machine-readable instructions and a processor 164 for executing said instructions to cause the NCE 160 to implement appropriate method steps. Similarly, the central management platform module 170 comprises at least a memory 172 for storing machine-readable instructions and a processor 174 for executing said instructions to cause the central management platform module 170 to implement appropriate method steps.

Each NCE 160 is preferably configured to at least intelligently implement regional traffic management, define and to provide new and updated traffic policies to the EGWs 120, and coordinate multiple EGWs 120.

The central management platform module 170 is preferably configured to at least intelligently implement whole network traffic management, define traffic strategies for the NCEs 160, and to manage and analyze network wide traffic data. The central management platform module 170 may comprise a cloud-based system and may connect to the NCEs 160 via an IP network such as an internet or a virtual private network (VPN).

The aspects of the invention may be implemented in any or all of the RSUs 130, the EGWs 120, the NCEs 160, and the central management platform module 170.

In the following description of specific embodiments of the present invention, the sensors for placement comprise LiDAR sensors and the target environment comprises a road traffic environment. However, it will be understood that this does not limit the present invention to the specific embodiments.

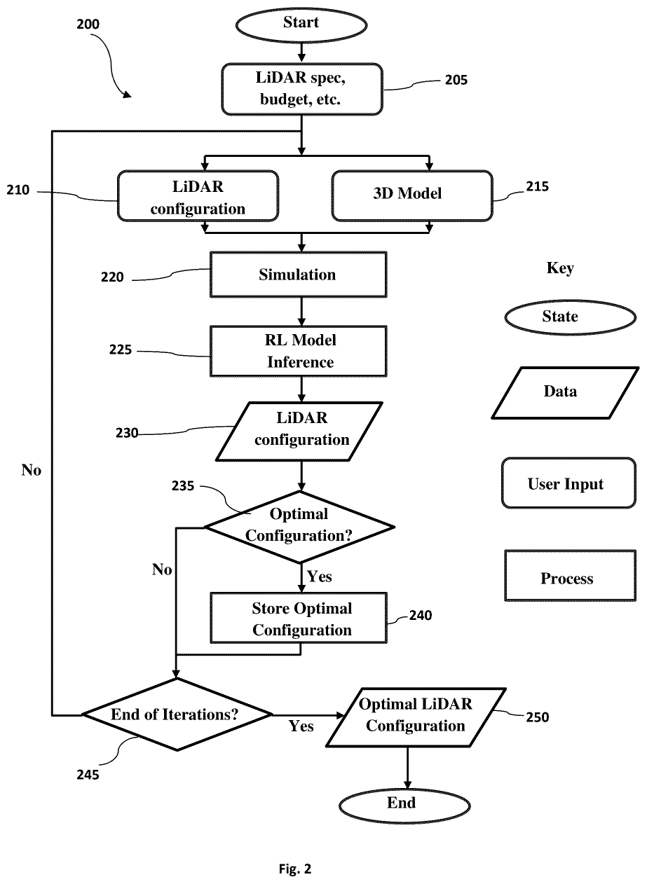

FIG. 2 is a schematic flow diagram of the applied method 200 in accordance with one aspect of the invention. The applied method 200 comprises a first user input step 205 of uploading a specification for the LiDAR sensors 180 to be placed in the target environment 110A, 110B comprising a real-world road traffic environment. The LiDAR specification may comprise data defining LiDAR detection range, range precision and accuracy, FOV size, point cloud scan pattern, crosstalk immunity, and detection rate, for example. It is assumed that all of the LiDAR sensors 180 to be placed have the same specification. In addition to the LiDAR specification, the first user input step 205 preferably includes uploading one or more constraints relating to the placement of the LiDAR sensors 180 in the target environment 110A, 110B. One such constraint may comprise budget data, i.e., a maximum cost for the placement process preferably taking into account factors such as the cost of the sensors, labor and material costs, and other related construction/installation costs. Another constraint may be the identification of areas in the target environment 110A, 110B where LiDAR sensors 180 may be placed and/or identification of areas in the target environment 110A, 110B where LiDAR sensors 180 must not be placed. The first user input step 205 may also include inputting data defining one or more conditions in the target environment 110A, 110B such as traffic flow level(s), for example.

The applied method 200 comprises a second user input step 210 of uploading LiDAR configuration data. The LiDAR configuration data preferably comprises indication of a number of a plurality of LiDAR sensors 180 to be placed in the target environment 110A, 110B. It preferably also includes a set of LiDAR placement configuration parameters. The placement configuration parameters may comprise data defining height, and pitch and/or yaw angles of the LiDAR sensors 180. It may also include location coordinates (e.g., x, y, z coordinates) as initial placement locations for the LiDAR sensors 180.

The applied method 200 comprises a third user input step 215 of uploading a 3D model of the target environment 110A, 110B. In one embodiment, the 3D model may comprise a 3D map of the target environment 110A, 110B. In another embodiment, the 3D model may comprise data defining optimal placement of LiDAR sensors 180 for defined scenarios in addition to the 3D map of the target environment 110A, 110B. The data defining optimal placement of LiDAR sensors 180 may be obtained by the training method aspect of the invention and may define optimal placement of LiDAR sensors 180 in one or more scenarios found within the target environment 110A, 110B. For example, such scenarios may comprise a “T”-junction, a cross-roads, a road intersection, or a highway.

The applied method 200 comprises a first process step 220 by which the received data inputted in the first, second and third user input steps 205, 210, 215 is processed by a simulation platform to simulate operation of the plurality of LiDAR sensors 180 to generate a dataset comprising simulated output data for the plurality of LiDAR sensors 180. The simulation platform may be implemented by execution of machine code stored in the memory 132 of an RSU 130 by the processor 134 of the RSU 130 and/or in any suitable network device such as the EGWs 120, the NCEs 160, and the central management platform 170. One preferred simulation platform comprises the known CARLA™ simulator. CARLA is an open-source simulator for autonomous vehicle research. It comprises a scalable client-server architecture in which a server is responsible for everything related to the simulation itself: sensor rendering, computation of physics, updates on the world-state and its actors and much more. A client side consists of a sum of client modules controlling the logic of actors on scene and setting world conditions. This is achieved by leveraging the CARLA API (in Python or C++), a layer that mediates between server and client. The client modules include a traffic manager which comprises a system that takes control of the vehicles besides the one used for learning. It acts as a conductor provided by CARLA to recreate urban-like environments with realistic behaviors, sensors which, in CARLA, are a specific kind of actor whose data can be retrieved and stored, and a recorder which reenacts a simulation step by step for every actor and grants access to any moment in the timeline. Other client modules may include a scenario runner providing a series of routes describing different situations to iterate on, and open assets which facilitate different maps for urban settings and a blueprint library with a wide set of actors to be used. However, these elements can be customized, and new scenarios can be generated. Other known network-based simulator which could be used comprise Autoware™ (Gazebo) simulator, Airsim™ (UE4 & Unity) simulator, or TORCS™ (Open GL) simulator.

The applied method 200 comprises a second process step 225 comprising a RL model inference step by which an RL algorithm or model determines from the dataset comprising the simulated output data for the plurality of LiDAR sensors 180 an optimized or at least an improved set of placement configuration parameters for the plurality of LiDAR sensors 180. The RL model inference step 225 can be considered as comprising a “querying” process by which users obtain suggested answers from the model predictions. During deployment, the RL algorithm or model parameters are preferably kept static or frozen. The RL algorithm or model may be implemented by execution of machine code stored in the memory 132 of an RSU 130 by the processor 134 of the RSU 130 and/or in any suitable network device such as the EGWs 120, the NCEs 160, and the central management platform 170. An RL model is an interdisciplinary area of machine learning and optimal control concerned with how an intelligent agent ought to take actions in a dynamic environment in order to maximize the cumulative reward. A typical framing of an RL scenario comprises an agent taking actions in a target environment, which is interpreted into a reward and a representation of the state, which are fed back into the agent. RL can be modelled as a Markov decision process. One purpose of RL is for the agent to learn an optimal, or nearly-optimal, policy that maximizes the “reward function” or other user-provided reinforcement signal that accumulates from the immediate rewards. In the applied method 200, a preferred reward parameter for the RL algorithm or model comprises simulated coverage area for each of the plurality of LiDAR sensors 180. The simulated coverage area for each of the plurality of LiDAR sensors 180 preferably comprises using simulated 3D point cloud data for each of the plurality of LiDAR sensors 180 and approximating the simulated 3D point cloud data. Approximating the simulated 3D point cloud data may be based on point distance, point cloud density, and point distribution uniformity. Alternatively, approximating the simulated 3D point cloud data may comprise representing the 3D point cloud data as data on a 2D grid and applying the L1 Norm (Manhattan Distance) to each data point in 2D grid. The L1 Norm is also known as the Manhattan Distance or Taxicab norm (when X=1). The L1 Norm is the sum of the magnitudes of the vectors in a space. It is the most natural way of measuring distance between vectors, which is the sum of absolute difference of the components of the vectors. This may include dividing the 2D grid into rectangular boxes, assigning “x” and “y” coordinates to each data point in the rectangular boxes applying the Manhattan Distance to each data point in the rectangular boxes.

In one embodiment, the second process step 225 comprising the RL model inference process enables LiDAR sensor placement configuration parameters to be automatically inferred according to the environment contexts and the LiDAR sensor specification using data generated from the training method as hereinafter described. This enables the second process step 225 to be computationally more efficient in that it can use simulated data for various roadside scenarios to infer optimal or improved LiDAR sensor placement configuration parameters without repeating the reward parameter valuation steps.

The second process step 225 of applied method 200 outputs LiDAR sensor placement configuration data in a first data step 230. This may comprise an optimal or at least improved set of placement configuration parameters for the LiDAR sensors 180 in the target environment 110A, 110B when compared to the user inputted initial placement configuration parameters.

In first decision step 235, an assessment is made as to whether or not the outputted LiDAR sensor placement configuration data in first data step 230 comprises the optimal or at least a sufficiently improved set of placement configuration parameters for the LiDAR sensors 180 in the target environment 110A, 110B. If it is decided “yes” then, in a third process step 240, the optimal or at least sufficiently improved set of placement configuration parameters is stored. If it is judged at second decision step 245 that no additional or further iterations of the applied method 200 are required, the optimal or at least sufficiently improved set of placement configuration parameters is outputted in second data step 250 and the applied method 200 ends. However, if it is decided at first decision step 235 that the outputted LiDAR sensor placement configuration data in first data step 230 does not comprise the optimal or at least a sufficiently improved set of placement configuration parameters and it is then decided, at second decision step 245, that further iterations of the applied method 200 are required, the applied method 200 returns to the second and third user input steps 210, 215 where adjustments to inputted data may be made. Adjustments to inputted data at the second and/or third user input steps 210, 215 may comprise changing the specification of the LiDAR sensors 180 such as inputting a specification for a different model of LiDAR sensor 180, or it may comprise adjusting one or more of the defined conditions such as a traffic flow level, or adjustments to one or more of the placement configurations parameters.

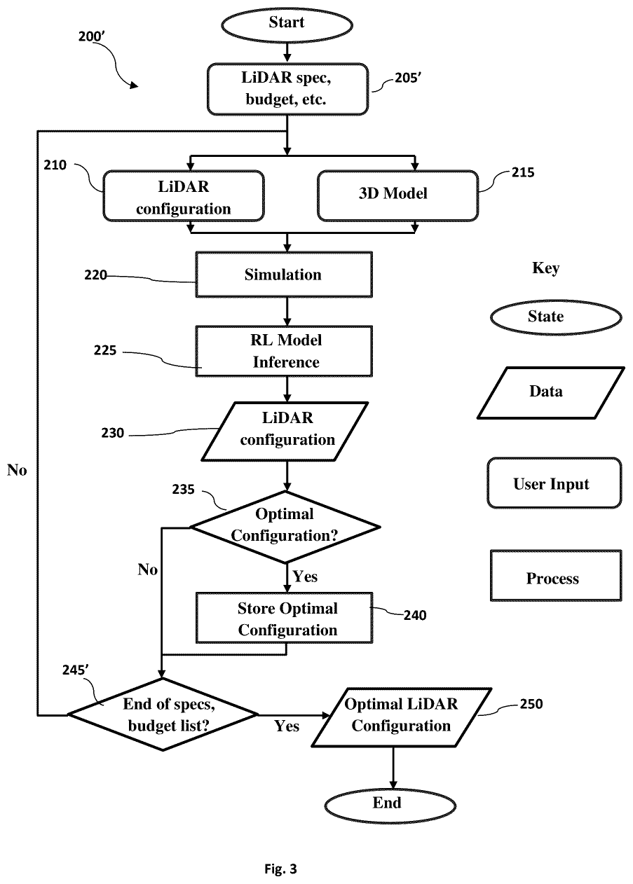

FIG. 3 is a schematic flow diagram of the applied method 200′ in accordance with another aspect of the invention. The applied method 200′ of FIG. 3 differs from that of the applied method of FIG. 2 in that the first user input step 205′ includes inputting a plurality or list of specifications for different models of LiDAR sensors 180, and/or a plurality or list of different constraints such as different budgets, and/or a plurality or list of different defined conditions. The applied method 200′ of FIG. 3 also differs from that of the applied method of FIG. 2 in that the second decision step 245′ determines if the method has been applied to all of the inputted lists of specifications for different models of LiDAR sensors 180, and/or different constraints, and/or different defined conditions. In all other respects, the applied method 200′ of FIG. 3 follows the same steps as the applied method 200 of FIG. 2 and therefore like numerals are used to denote like steps. The applied method 200′ of FIG. 3 in effect allows all ‘adjustments’ to be inputted in the first user input step 205′ before commencement of the applied method 200′ and for the applied method 200′ to iterate through all possibilities to determine an optimized or at least an improved set of placement configuration parameters for the plurality of LiDAR sensors 180.

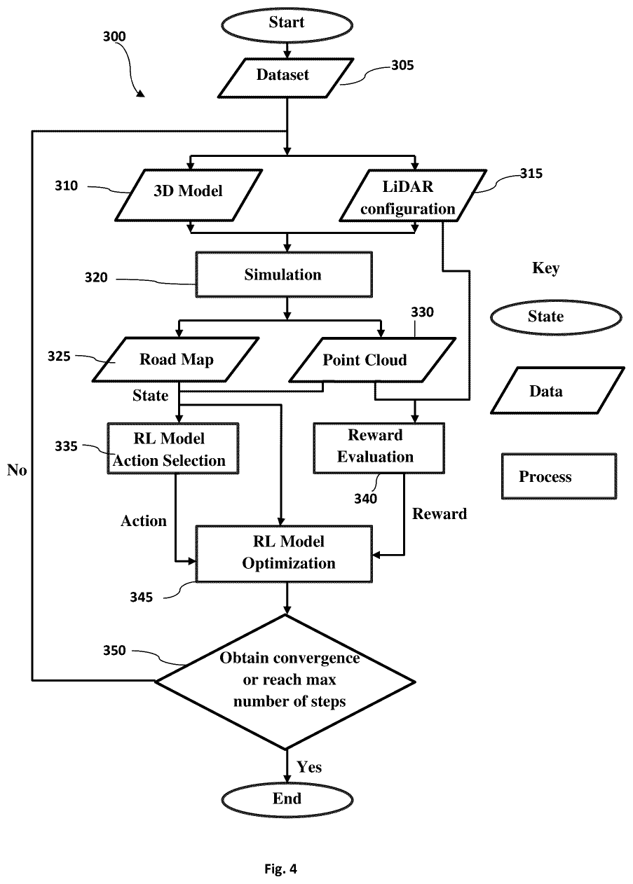

FIG. 4 is a schematic flow diagram of a training method 300 in accordance with an aspect of the invention. The method 300 may be implemented by execution of machine code stored in the memory 132 of an RSU 130 by the processor 134 of the RSU 130 and/or in any suitable network device such as the EGWs 120, the NCEs 160, and the central management platform 170. Alternatively, the method 300 may be implemented in a standalone device or system.

The method 300 comprises in a first data step 305 receiving a dataset. The dataset may comprise a previously generated dataset provided by the simulator. The simulator preferably comprises the same simulation platform as used in the applied methods 200, 200′ of FIGS. 2 and 3. In a second data step 310, received is a 3D model of the target environment 110A, 110B. The 3D model may comprise a 3D map of the target environment 110A, 110B. In a third data step 315, received are LiDAR configuration data. The LiDAR configuration data preferably comprise an indication of a number of a plurality of LiDAR sensors 180 to be placed in the target environment 110A, 110B. It preferably also includes a set of LiDAR placement configuration parameters. The placement configuration parameters may comprise data defining height, and pitch and/or yaw angles of the LiDAR sensors 180.

In a first process step 320, the simulator generates a universal training dataset based on the 3D model of the target environment 110A, 110B, and the LiDAR configuration data. Data outputs from the simulator include simulated road map data outputted in a fourth data step 325 and simulated LiDAR sensor scans preferably in the form of point cloud LiDAR sensor scan data in a fifth data step 330. The road map data derived from the 3D model can be inputted to a second process step 335 comprising an RL model action selection process whereby a selection is made of a road scenario for RL model optimization. The road map data derived from the 3D model can also be inputted directly to a fourth process step 345 comprising the RL model optimization. The point cloud LiDAR sensor scan data from the fifth data step 330 is passed to a third process step 340 to determine a reward valuation parameter for the RL model optimization. The method of determining reward valuation parameter for the RL model optimization preferably comprises the afore-described RL model reward value determination as used in the applied methods 200, 200′ of FIGS. 2 and 3. In the fourth process step 345, for optimization, the RL model is tuned and/or trained with RL model updates with respect to reward parameter value feedback, but iteratively until, at first decision step 350, a determination is made that convergence of an optimized set of placement configuration parameters has been obtained or a predefined maximum number of steps or iterations has been reached.

Other aspects and more specific examples of implementations of the aspects of the invention follow.

The aspects of the invention as illustrated by FIGS. 2 to 4 are directed to a method for automatic placement optimization of roadside sensors such as LiDAR sensors 180 in a target environment 110A, 110B. Given data defining the 3D target environment as input to a processor implemented simulation platform such as a game engine-based simulator, LiDAR sensor scans from RSUs 130, for example, can be simulated to create a training environment for Reinforcement Learning (RL). With respect to sensor configuration and budget constraints, the model will output optimal or at least improved solutions for multi-LiDAR sensor placement and set-up in the target environment 110A, 110B. An optimal solution preferably includes, for each LiDAR, its location (x, y, z coordinates) and its angles (pitch, yaw). The coordinate system (x, y, z) is preferably a global coordinate system, but could comprise any suitable coordinate system for the target environment. Depending on factors such as budget constraints, the aspects of the method of the invention can be used to return a most economical set of solutions after iterating over a given list of LiDAR sensor candidates whilst comparing their collective scanning efficiency.

More specifically, with the assistance from the game engine-based simulator, a universal training dataset for automatic roadside sensor placement is generated from the 3D environment, including scene context information such as road map data and LiDAR sensor scan data. A game engine-based simulator is built using a game engine. It leverages the capabilities of the engine to create a virtual environment for various purposes, such as training and testing autonomous agents, conducting research, or developing virtual reality experiences. Game engines offer features like rendering realistic graphics, handling physics-based interactions, and managing complex scenes.

The RL model is trained on the generated dataset. At each step, given context information, an action to adjust LiDAR sensor configuration is sampled and correspondingly simulated to obtain LiDAR scan data for collective coverage estimation, which serves as a proxy score or reward parameter value indicative of adjustment quality for the RL model optimization process.

The aspects of the method of the invention eliminate the need for exhaustive searches for optimal sensor placement configurations settings or parameters for every roadside scenario. Utilizing a convergent RL model enables optimal scene-adaptive configurations to be automatically inferred according to the environment contexts and LiDAR sensor specifications.

For simulation purposes, the inputted ‘LiDAR configurations’ preferably comprise geographic information that logs absolute location coordinates in the simulator, but other coordinate systems may be used. For each LiDAR sensor, configuration information includes (x-coordinate, y-coordinate, z-coordinate, pitch angle, and yaw angle). The user should also indicate initial LiDAR sensor locations for initialization purposes which informs the RL model of the maximum number of sensors allowed. The RL model will then begin optimization from this initial state to more efficiently converge towards the objective of optimal LiDAR sensor placement taking into account the inputted data such as LiDAR sensor specification(s), constraints on placement, and any defined conditions for the target environment.

After starting simulation with the defined conditions e.g. traffic flow and LiDAR sensor set-up, the LiDAR sensors 180 begin to collect and save data, in the form of any one or more of: RGB images; point cloud scans; bird's-eye-view road maps, object detection bounding boxes, etc. In one embodiment, the LiDAR sensor point cloud scan data can be used as a surrogate metric for point cloud scan data quality.

Upon model optimization and output of optimal LiDAR sensor placement configuration parameters, the simulator can also be used to generate datasets with sensor point cloud scans and bounding box ground truths for conventional 3D object detection model training.

A list of LiDAR sensor model type with corresponding cost information can be fed into the simulator to obtain optimal LiDAR sensor placement configuration parameters with improved or optimal accuracy and lowest cost by iterating through each LiDAR sensor model type. In this context, it is assumed that each iteration considers only one type of LiDAR sensor model, i.e., that the inputted number of allowed LiDAR sensors all comprise the same sensor model type.

The simulation software, e.g. CARLA™, provides rich varieties of data modality, e.g. semantic segmentation, point cloud scans, depth maps, and bounding box ground truth of vehicles for object detection tasks. This functionality is utilized to generate a universal dataset for pre-training of the RL model sampled from a diverse myriad of roadside scenarios, e.g. intersections, T-sections, highways, crossroads, etc. The universal training dataset comprises a series of “state”, “action”, “reward” sequences where “state” comprises the LiDAR sensor configurations, “action” comprises LiDAR sensor configuration adjustments, and “reward” comprises the LiDAR sensor point cloud metric derived from the point cloud scan data.

The aspects of the invention involve a RL learning framework catered for LiDAR sensor configurations, although it will be understood that the aspects of the invention are not limited to LiDAR sensor configurations.

RL comprises a deep learning mechanism that allows an agent to explore in a pre-defined or target environment and conclude with an optimal strategy or solution through a trial-and-error process. For each iteration, given observations of the environment state, an agent performs actions and receives reward to generalize an optimal strategy or solution. The environment can be considered as a pre-defined world with constraints which the agent resides in and interacts with for exploration in order to optimize the reward value. The simulation is a world in which the model adjusts LiDAR sensor placement configuration parameters to obtain an optimal set of placement configuration parameters. The state is a situation in the environment which is influenced by the agent's actions at each timestamp of the process. An action is an action conducted by the agent which brings forth interactions within the environment. The reward or reward parameter value is a quantified score of interactions that contributes to reinforcement on the agent's behavior.

The aspects of the invention may include a novel point cloud scan coverage metric with enhanced efficiency. This involves a change of the metric score derived from LiDAR sensor point cloud coverage data coupled with the number of LiDAR sensors deployed to optimize for high coverage with minimum resource usage.

This is encompassed in Algorithm 1 below:

Algorithm 1 K-step on policy Proximal Policy Optimization with Episodic Reward
Initialize network parameters θ for policy π_{θ}, and φ for value function V_{φ}.
Initialize empty replay buffer D.
Initialize N environment processes.
Require: metric function f(s), number of episodes M, number of steps per episode K,

| | |
|---|---|
| | discount factor γ, number of minibatch samples N, PPO-Clip parameter ε. |
| | for episode = 1, M do |
| | Receive initial observation state s₁, // e.g. BEV map, point cloud scan |
| | for t = 1, K do |
| | Select action aₜ = π_{θ} (sₜ) + Nₜ according to the current policy. |
| | Execute action aₜ and observe new state sₜ₊₁. |
| | if t = K then |
| | Receive reward rₜ = f(sₜ) - f(s₁). |
| | Store transition (sₜ, aₜ, rₜ, sₜ₊₁) in D. |
| | else |
| | Store transition (sₜ, aₜ, 0, sₜ₊₁) in D. |
| | end if |
| | sₜ = sₜ₊₁. |
| | end for |
| | for i = 1, N do |
| | Receive final reward r_{K+1}. |
| | if Nᵢ converged then |
| | Re-initialize environment process i. |
| | end if |
| | end for |
| | Sample a random minibatch of N transitions (sᵢ, aᵢ, rᵢ, sᵢ₊₁) from D. |
| | Set yᵢ = rᵢ if episode terminates at step i + 1, otherwise set yᵢ = rᵢ + γVφ(sᵢ₊₁). |
| | $Update the value function by minimizing the loss : L ( φ ) = \frac{1}{N} {\sum }_{i} {( {y}_{i} - {V}_{φ} ( {s}_{i} ) )}^{2} .$ |
| $\frac{1}{N}$ | Update the policy by maximizing PPO-Clip objective: |
| $\frac{1}{N}$ | L(θ) = Σᵢ min(rₜ(0) Âₜ, clip(rₜ(θ), 1 − ε, 1 + ε) Âₜ). |
| | end for |

where “episode” comprises a sequence of state, action, reward, and consequent state;
“policy π(s)” comprises a neural network parametrized function that determines optimal actions upon observing current state;
“value function V(s)” comprises a neural network parametrized function that approximates quantified score of state which agent chooses to enter; and
“proximal Policy Optimization (‘PPO’)” comprises a regularization technique to stabilize policy update by restraining adjustment to be within defined threshold F.

The aspects of the invention may involve a model learning set-up procedure.

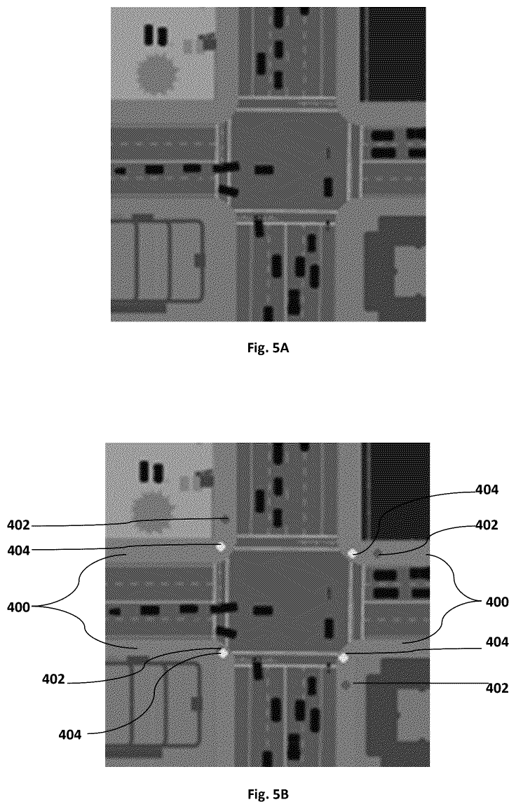

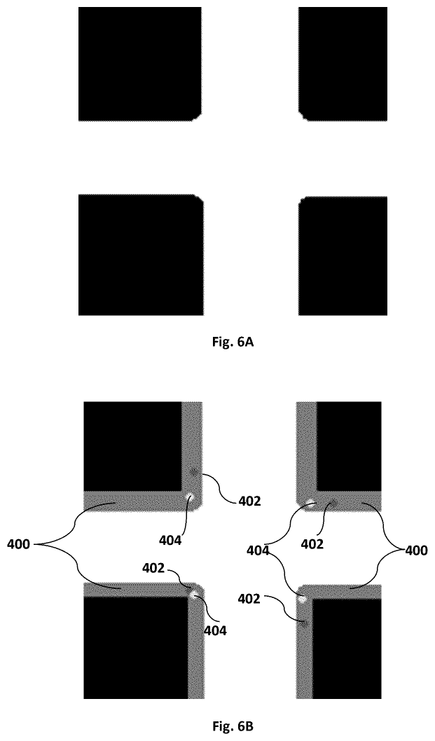

Referring to FIGS. 5A, B and FIGS. 6A, B, considering conventional road regulations, placement of smart traffic sensors such as LiDAR sensors 180 have to abide by defined rules subject to traffic conditions, e.g., height limit and area range. Constraints are used for ‘action masking’ for the sake of complexity reduction and avoiding invalid optimization, e.g., placing sensors on roadways or on areas not designated for roadside infrastructure such as gardens or parkland or the like.

The agent of the RL model is able to adapt to various conditions upon receiving the relevant or appropriate constraint data inputs. At each timestamp of the process, the agent is provided with a road map to extract representations of road types such as shown by way of example in FIGS. 5A, B. The example of FIGS. 5A, B show a crossroads. Other examples of road types include intersections, T-junctions, or highways, etc. The road map, with a bird's-eye-view (BEV) angle, can either be in the form of a semantic segmentation, with complete set of object categories for thorough information, as illustrated in FIGS. 5A, B or a binary mask that indicates the presence of roads as a minimum input as shown in FIGS. 6A, B.

In FIGS. 5A, B, the areas on which LiDAR sensors 180 can be placed are indicated by numeral 400. For each iteration update of the road map, the LiDAR sensor locations are preferably indicated on the road map to inform the agent model of any executed adjustment. Consequently, the agent model becomes aware of the adjustment with respect to the area range limit. Comparing FIG. 5A to FIG. 5B, LiDAR sensor locations in timestep t are indicated by numeral 402 whilst LiDAR sensor locations in timestep t+1 are indicated by numeral 404. The LiDAR sensor configurations can be represented as one-hot vector e.g. [L1, L2, L3, L4].

In a similar manner and using the same numerals, the areas on which LiDAR sensors 180 can be placed in FIGS. 6A, B are indicated by numeral 400 and comparing FIG. 6A to FIG. 6B, LiDAR sensor locations in timestep t are indicated by numeral 402 whilst LiDAR sensor locations in timestep t+1 are indicated by numeral 404.

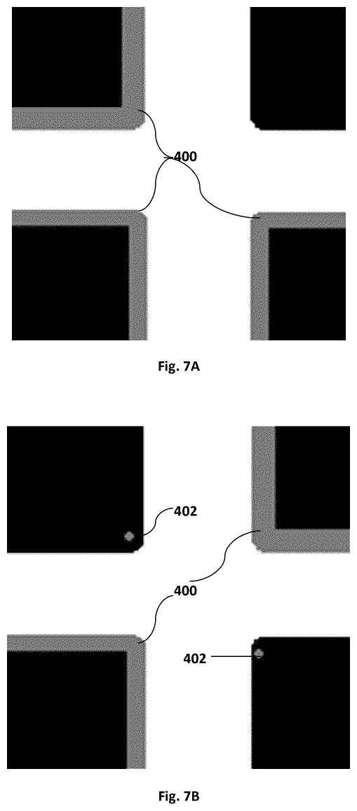

Referring now to FIGS. 7A, B, some use cases can be provided by way of example.

During deployment, in a first example case of unexpected breakdowns of particular sensors, users can update the permitted area for LiDAR sensor placement and input an adjusted scenario to obtain a new optimal or improved solution for LiDAR sensor placement configuration parameters. Comparing FIG. 7A to FIG. 7B, it can be seen that the roadside scenario of FIG. 7A has been updated or adjusted to remove one of the four permitted areas for LiDAR sensor placement. In this case, the 2^{nd} LiDAR sensor in the top right corner is not operational. This could be due to damage or mal functioning. FIG. 7A comprises the updated road map with the previously permitted area in the top right corner being masked out and the LiDAR vector configuration now comprises [L1, None, L3, L4]which will be utilized in the method of FIG. 3, for example, to determine a new set of Lidar sensor placement configuration parameters for the adjusted sensor set-up.

In a second example case as illustrated in FIG. 7B where a subset of sensors needs to be dynamically adjusted while holding others fixed, the method of FIG. 3, for example, can be effectively configured to cater for such a case by defining action constraints on certain sensors, e.g. when the 1^{st} and 3^{rd} are expected to be fixed while only optimizing the 2^{nd} and 4^{th} sensors, the LiDAR sensor configurations can be masked with [L1′, L2, L3′, L4] with which each adjustment towards the 1^{st} and 3^{rd} LiDAR sensors will be omitted.

In a third example case where the sensors are equipped with an advanced rotating function (i.e., flexible pitch and yaw angles), the method of FIG. 3 can be applied dynamically and continually, since the sensors have flexible movement. This is as opposed to conventional sensors which are affixed after installation and need manual re-adjustment. In the case of an unexpected event such as a typhoon or vision blockage caused by an obstruction such as an illegally parked truck or roadworks, etc., after an anomaly detection such as an unexpected malfunction, which can be achieved by comparing a current frame with preceding frames in terms of data quality/noise difference, a new back-up LiDAR sensor placement solution can be obtained following the methodology of the first example case.

The aspects of the invention may include improved method of determining the value of the reward parameter.

To accelerate the reward parameter value determination process, it is proposed to use a surrogate metric to directly approximate the LiDAR sensor point cloud data quality from each LiDAR sensor movement to indicate scanning coverage, which in turn serves to be a theoretical proxy to reflect expected evaluation accuracy of object detection models to be trained on collected point cloud data.

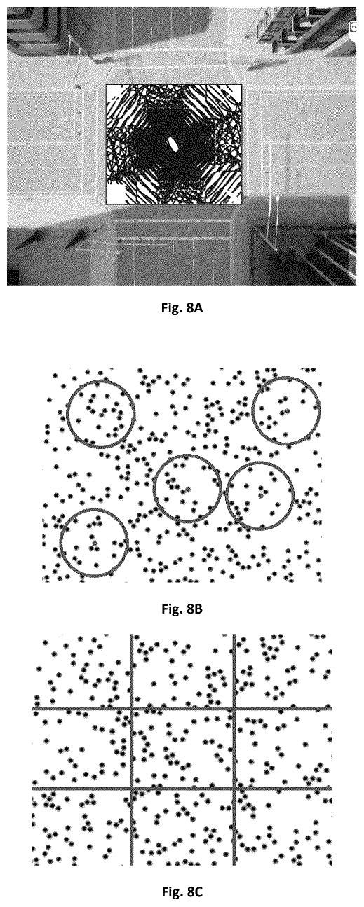

In the case of LiDAR sensor point cloud scan data received for a particular roadside scenario comprising a targeted road intersection region having zero traffic flow as shown in FIG. 8A, the surrogate metric score can be calculated from a ratio of formulated count/distance to the hypothetical average assuming that all points are uniformly distributed. The zero-traffic flow: comprises a stationary scene with no vehicles but only the road conditions.

Considering the case where much uncertainty would occur should a blockage of sensor vision occur due to, for example, large sized vehicles in front of a sensor. If such a blockage lasts for a temporary period, then the sensor monitoring function will resume and this should not pose much concern. However, if, on the other hand, sensor malfunctions or breakdowns caused by unexpected natural events such as typhoons occur, this requires additional inspection and the aspects of the method of the invention can be utilized to generate new LiDAR sensor placement solution according to the third example case described above.

One method of determining a value of the surrogate metric comprises applying leveraged sampling to selected circular disk regions of a 2D projection of the 3D point cloud scan data and to then count the number of LiDAR points in the selected circular disk regions of the 2D projection as illustrated in FIG. 8B.

This is encompassed in Algorithm 2 below:

Algorithm 2 Surrogate metric from selected circular disk regions:

```
Require: number of sampling points Nₚ, disk radius r, point cloud P.
  Initialize subset of point cloud P’ by sampling Nₚ points from P // used as point cloud
  centers for evaluation.
  Initialize empty list S ∈ R^{Np} // for storing score of each region
  i := 0
  for each point p’ in P’ do
    S[i] := 0
    for each point p in P do
      distance := || p − p’ ||₂
      if distance ≤ r then
        S[i] := S[i] + 1
      endif
    end for
    i := i + 1
  end for
  // Computer metric using S
```

Another method of determining a value of the surrogate metric comprises measuring the distance between each point in the selected regions with its nearest neighbor, but this requires some trade-offs. The sampling process consists of hyperparameters i.e., variables that require manual tuning, including the number of disks and their radius. Less sampling gives sparse population which is unrepresentative, but larger values cover a wider area, though at the cost of increasing computation. The selection process comprises distance calculation in ‘Euclidean Distance’ which computes squared distance of sampled anchor points to every other point for filtering.

In view of the limitations of the above method, the preferred method is based on rectangular grid regions in the 2D projection as illustrated in FIG. 8C. The preferred method leverages the 2D rectangular property to apply binarization by uniformly dividing the region into grids to consider the entire area instead of sampling subject to pre-defined radius of selected areas. Rather than using circular disks, the preferred method uses rectangular boxes which enables the application of the L1 Norm (Manhattan Distance) that provides higher computation efficiency. Rather than comparing points in Euclidean distances, the preferred method just compares and masks points with respect to x- and y-coordinates.

More specifically, the target region (FIG. 8C) is split into grids, to which each point is assigned x- and y-coordinates. This reduces the complexity is reduced to O(|P|) (algorithm 3) by removing previously required parameters. The entire region, rather than a few randomly sampled areas, is taken into account.

This is encompassed in Algorithm 3 below:

Algorithm 3 preferred method of determining the surrogate metric:

```
Require: road region dimensions (H, W), sampling grid size s, point cloud P
  Initialize zero 2-D array S ∈ R^{┌H / s┐} ^{×} ^{┌W / s┐} to store metric score of each grid //
  // s can also be defined w.r.t. H and W separately e.g. sampling grid size (┌H / h┐, ┌[ / w┐)
  for each point p in P do
    i := ┌pₓ / s┐ // index of grid
    j := ┌p_{y} / s┐
    S[i, j] := S[i, j] + 1
  end for
  // Computer metric using S
```

Details of metric computation using point list M is as follows, where InfraDensity computes density and InfraNUC computes uniformity:

$$InfraDensity = \frac{N}{S}$$

$$Average = \frac{1}{D} {\sum }_{i = 1}^{D} \frac{{n}_{i}}{N \cdot p}$$

$$InfraNUC ( “ Normalized Uniformity Coefficient ” ) = \sqrt{\frac{1}{D} {\sum }_{i = 1}^{D} {( \frac{{n}_{i}}{N \cdot p} - Average )}^{2}}$$

where N=number of points;
S=region area;
I=index of grids (rectangular boxes);
ni=ith grid;
p=area ratio of grid to whole region; and
D=number of grids.

The aspects of the invention may also include traffic index attention.

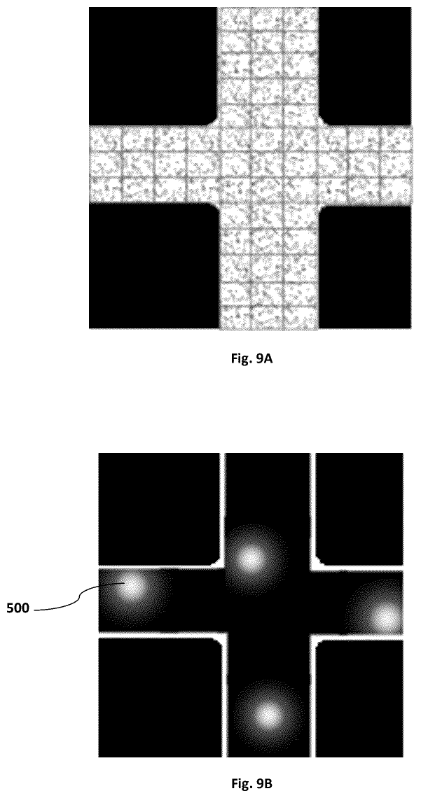

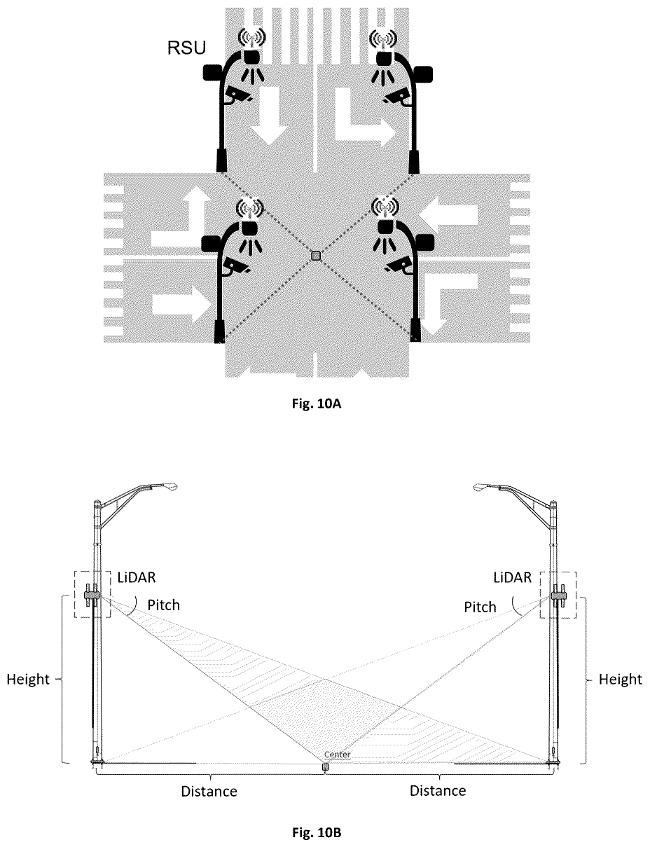

Traffic Index (TI) assigns attention to road sections with respect to importance of traffic conditions, e.g., dense traffic flow regions, pedestrian regions, accident prone regions, common blind areas, speed limits. This preferably comprises a user-specified input, otherwise the TI mask is not used, and all regions will be given equal weight for consideration. More specifically, the TI is based on multiplying the point cloud scan (P) as illustrated in FIG. 9B with weights from a Traffic Index∈{0, 1} as visually illustrated in FIG. 9B where the light regions or areas 500 have assigned to them a TI weight indicative of increased attention to such areas. This is then passed into the evaluation of the coverage metric (surrogate metric).

The aspects of the invention may also include a reduction in the number of initially designated sensors. Besides achieving good area coverage, it is equally useful to restrain the number of sensors for reasons of budget so an additional negative reward may be introduced to encourage minimal sensor deployment. For each roadside scene or scenario, the model is informed of the maximum number of sensors for initialization, e.g. 4 for a typical crossroads. The agent's action then also includes altering the sensor state with respect to a one-hot vector of Boolean flags (L), e.g. [1, 1, 1, 0] indicates that sensors 1, 2 and 3 are turned on and the 4^{th} sensor is off, meaning that the model is searching for a solution by utilizing only three sensors. This formulation relates to the third example case discussed above.

The aspects of the invention may also include multi-objective optimization with respect to multiple constraints comprising, for example, high overall scan coverage, high scan coverage in specifically intended region(s), and low number of sensors for budget control. A scan coverage metric comprises Metric(P, TI)=Density(P′)+InfraNUC(P′)

where P′=P·TI is the dot product of the weight multiplication. Overall, the objective function=w·M(P, TI)+(1−w)·|L|, where w=0.7 is a user-defined weighting constant to indicate emphasis on each objective. The values of w may differ for different scenarios.

Referring again to the reward parameter value (surrogate metric), the reward of the RL agent in each iteration is defined as the difference between the current state and the initial state. The agent is expected to start with a reasonable initialization condition for quicker convergence. It has been observed that, in the case of multi-sensor deployment, each sensor may complement other sensors' blind areas. When a seamless adjacency between the coverages is ensured, a more extensive field of views can be fostered, hence establishing a good initialization parameter.

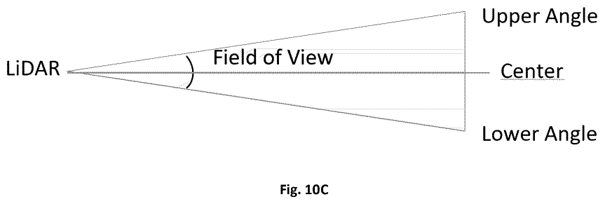

In one embodiment, it is proposed that, with a given height of a set of LiDAR sensors from initialization, the optimal pitch angle can be calculated as follows:
1) Compute a location of the center point amongst the sensors by averaging the x- and y-coordinates of the sensors (FIG. 10A);
2) Compute distance between each sensor and the center point (FIG. 10B); and
3) Compute and set up LiDAR sensors according to the lower pitch angle P_{lower} (FIG. 10C) where P_{lower}=tan⁻¹(height/distance).

Note that the pitch angle center can be obtained from the lower pitch angle with respect to the intrinsic FOV parameter of the LiDAR sensor, i.e., P_{center}=P_{lower}+(FOV/2).

Such initialization provides semi-ideal pitch and yaw angles for the framework to start with and decreases learning steps in the commencement of the training method 300. Throughout, optimization, configurations of (x, y, z) coordinates, will be adaptively adjusted for better convergence, and (pitch, yaw) angles will follow correspondingly for further updates.

The invention provides a novel method using RL to obtain generalized solutions in an end-to-end manner. The generated datasets comprise standard data sequences (state, action, reward) e.g., (LiDAR sensor configurations, configuration adjustments, point cloud quality), rendered for the RL model training and contains diverse scenarios that enables the RL model to generalize over. After training, the RL model will be robustly capable of predicting new optimal placement strategies under unseen use cases or scenarios. For LiDAR sensor configuration, road conditions may differ significantly from case to case, where there may exist intersections of roads, T-sections, or 2-way highways, along with divergent road connections. These pose an intricate challenge for the RL model. The novel introduction of scene maps serves as a dynamic learning module for the RL model to adapt to varying scenario contexts. The method aims to converge towards the objectives of high LiDAR sensor scan coverage area with low number of sensors deployed. In the RL model training process, point cloud map data are generated from the simulation of a LiDAR sensor being placed in the simulator world or platform which emits pulsed laser signals. Note, however, that the point cloud map is preferably recorded under a condition of assumed zero traffic flow, i.e., the point cloud data is generated for only the road structure.

One advantage of the method of the invention is to eliminate the need for exhaustive searches for optimal sensor settings for every scenario. With a converged RL model, optimal scene-adaptive configurations can be automatically inferred according to the environment contexts and sensor specifications.

The modules, units, and devices as described above may be implemented at least in part in software. Those skilled in the art will appreciate that the above described may be implemented at least in part using general purpose computer equipment or using bespoke equipment.

Here, aspects of the method and system described herein can be executed on any system or apparatus comprising the road monitoring system. Program aspects of the technology can be thought of as “products” or “articles of manufacture” typically in the form of executable code and/or associated data that is carried on or embodied in a type of machine readable medium. “Storage” type media include any or all of the memory of the mobile stations, computers, processors or the like, or associated modules thereof, such as various semiconductor memories, tape drives, disk drives, and the like, which may provide storage at any time for the software programming. All or portions of the software may at times be communicated through the Internet or various other telecommunications networks. Such communications, for example, may enable loading of the software from one computer or processor into another computer or processor. Thus, another type of media that may bear the software elements includes optical, electrical, and electromagnetic waves, such as used across physical interfaces between local devices, through wired and optical landline networks and over various air-links. The physical elements that carry such waves, such as wired or wireless links, optical links, or the like, also may be considered as media bearing the software. As used herein, unless restricted to tangible non-transitory “storage” media, terms such as computer or machine “readable medium” refer to any medium that participates in providing instructions to a processor for execution.

While the invention has been illustrated and described in detail in the drawings and foregoing description, the same is to be considered as illustrative and not restrictive in character, it being understood that only exemplary embodiments have been shown and described and do not limit the scope of the invention in any manner. It can be appreciated that any of the features described herein may be used with any embodiment. The illustrative embodiments are not exclusive of each other or of other embodiments not recited herein. Accordingly, the invention also provides embodiments that comprise combinations of one or more of the illustrative embodiments described above. Modifications and variations of the invention as herein set forth can be made without departing from the spirit and scope thereof, and, therefore, only such limitations should be imposed as are indicated by the appended claims.

In the claims which follow and in the preceding description of the invention, except where the context requires otherwise due to express language or necessary implication, the word “comprise” or variations such as “comprises” or “comprising” is used in an inclusive sense, i.e., to specify the presence of the stated features but not to preclude the presence or addition of further features in various embodiments of the invention.

It is to be understood that, if any prior art publication is referred to herein, such reference does not constitute an admission that the publication forms a part of the common general knowledge in the art.

1. A method of automatically determining sensor placement in a target environment, the method comprising:
receiving as inputs: a three-dimensional (3D) map of the target environment; a number of a plurality of sensors to be placed in the target environment; a set of placement configuration parameters for the plurality of sensors; and a set of constraints for the plurality of sensors in the target environment;
based on the received inputs, using a simulation platform to simulate, based on one or more defined conditions in the target environment, operation of the plurality of sensors to generate a dataset comprising simulated output data for the plurality of sensors; and
using a reinforcement learning (RL) algorithm to determine from the dataset comprising simulated output data for the plurality of sensors an optimized or at least an improved set of placement configuration parameters for the plurality of sensors.

2. The method of claim 1, wherein the method comprises:
using the simulation platform to generate respective datasets for a plurality of target environment scenarios; and
using the respective datasets to train the RL algorithm to determine optimized or at least improved sets of placement configuration parameters for the plurality of sensors for the plurality of target environment scenarios.

3. The method of claim 2, wherein one of the received inputs includes an optimized or at least an improved set of placement configuration parameters for one of the plurality of target environment scenarios.

4. The method of claim 2, wherein the method comprises using data generated for the respective datasets for the plurality of target environment scenarios to dynamically adapt to new or different target environment scenarios or scenes.

5. The method of claim 1, wherein the method is applied iteratively for a plurality of adjustments to the user inputted data to thereby determine an optimized or at least an improved set of placement configuration parameters for the plurality of sensors.

6. The method of claim 1, wherein the method is applied iteratively for a plurality of sensor model types, the sensor model types having different values for the constraints in the target environment, to thereby determine an optimized or at least an improved set of placement configuration parameters for the plurality of sensors including sensor model type.

7. The method of claim 1 wherein a reward parameter for the RL algorithm comprises simulated coverage area for each of the plurality of sensors.

8. The method of claim 7, wherein the method comprises maximizing sensor scan coverage areas to converge towards optimal sensor placement but taking into account a hybrid objective comprising any one or more of: budget for sensor placement; sensor specification(s); constraints on sensor placement; any defined conditions for the target environment.

9. The method of claim 7, wherein the simulated coverage area for each of the plurality of sensors comprises simulated 3D point cloud data for each of the plurality of sensors.

10. The method of claim 9, wherein the simulated 3D point cloud data for each of the plurality of sensors is approximated based on point distance, point cloud density, and point distribution uniformity.

11. The method of claim 10, wherein the 3D point cloud data for each of the plurality of sensors is approximated by:
representing the 3D point cloud data as a 2D grid; and
applying the L1 Norm (Manhattan Distance) to each data point in 2D grid.

12. The method of claim 11, wherein the method comprises:
dividing the 2D grid into rectangular boxes;
assigning “x” and “y” coordinates to each data point in the rectangular boxes; and
applying the L1 Norm (Manhattan Distance) to each data point in the rectangular boxes.

13. The method of claim 1, wherein the method comprises, in one or more iterations, reducing the number of a plurality of sensors to be placed in the target environment and determine an optimized or at least an improved set of placement configuration parameters for the reduced number of sensors.

14. The method of claim 1, wherein the method comprises inputting the set of placement configuration parameters for the plurality of sensors as an initial set of placement configuration parameters and iteratively implementing the method for respective adjustments of one or more of the placement configuration parameters to determine an optimized or at least an improved set of placement configuration parameters for the plurality of sensors.

15. The method of claim 14, wherein the initial set of placement configuration parameters are selected to provide a semi-optimal direction for the RL model where said initial set of placement configuration parameters are mathematically calculated using trigonometry from data defining the target environment or a target environment scenario.

16. The method of claim 1, wherein one or more weighting values applied to one or more of the constraints in the set of constraints for the plurality of sensors in the target environment.

17. The method of claim 1, wherein the plurality of sensors comprises light detection and ranging (LiDAR) sensors and the target environment comprises a road traffic environment.

18. The method of claim 1, wherein the simulation platform comprises any of: a CARLA simulator for autonomous driving research; an Autoware (Gazebo) simulator; an Airsim (UE4 & Unity) simulator; or a TORCS (Open GL) simulator.

19. The method of claim 1, wherein the RL algorithm comprises a universal RL model.

20. An apparatus for automatically determining roadside sensor placement in a target environment, the apparatus comprising a memory for storing machine-readable instructions and a processor for executing said machine-readable instructions configuring the processor to implement the steps of:
receiving as inputs: a three-dimensional (3D) map of the target environment; a number of a plurality of sensors to be placed in the target environment; a set of placement configuration parameters for the plurality of sensors; and a set of constraints for the plurality of sensors in the target environment;
based on the received inputs, using a simulation platform to simulate, based on one or more defined conditions in the target environment, operation of the plurality of sensors to generate a dataset comprising simulated output data for the plurality of sensors; and
using a Reinforcement Learning (RL) algorithm to determine from the dataset comprising simulated output data for the plurality of sensors an optimized or at least an improved set of placement configuration parameters for the plurality of sensors.

21. A non-transitory computer readable medium comprising machine-readable instructions which, when executed by a processor, causes the processor to implement the steps:
receiving as inputs: a three-dimensional (3D) map of the target environment; a number of a plurality of sensors to be placed in the target environment; a set of placement configuration parameters for the plurality of sensors; and a set of constraints for the plurality of sensors in the target environment;
based on the received inputs, using a simulation platform to simulate, based on one or more defined conditions in the target environment, operation of the plurality of sensors to generate a dataset comprising simulated output data for the plurality of sensors; and
using a Reinforcement Learning (RL) algorithm to determine from the dataset comprising simulated output data for the plurality of sensors an optimized or at least an improved set of placement configuration parameters for the plurality of sensors.
